(19) United States
(12) Patent Application Publication
(10) Pub. No.: US 2011/0025723 A1
(43) Pub. Date: Feb. 3, 2011

(54) Pixel structure and organic light emitting display using the same

(76) Inventor: Eunah Kim, Yongin-City (KR)

Correspondence Address: LEE & MORSE, P.C., 3141 FAIRVIEW PARK DRIVE, SUITE 500, FALLS CHURCH, VA, 22042, US

(21) Appl. No.: 12/662,868

(22) Filed: May 7, 2010

(30) Foreign Application Priority Data
Aug. 3, 2009 (KR) 10-2009-0071278

(51) Int. Cl. G09G 5/10; H01L 33/36

(52) U.S. Cl. 345/690; 257/89; 257/E33.061; 345/76

(57) ABSTRACT

A pixel that is adapted for implementing higher definition and an organic light emitting display using such a pixel are provided. The pixel includes a red sub-pixel including a red emitting layer, a green sub-pixel including a green emitting layer, a first blue sub-pixel including a first blue emitting layer, and a second blue sub-pixel including a second blue emitting layer. The red emitting layer and the green emitting layer are symmetrically arranged and the first blue emitting layer and the second blue emitting layer are symmetrically arranged.

### BACKGROUND

1. Field

Embodiments relate to a pixel structure and an organic light emitting display including such a pixel structure. More particularly, embodiments relate to a pixel structure capable of reducing a size of a light emitting unit of a pixel and an organic light emitting display including such a pixel structure.

2. Description of the Related Art

Organic light emitting flat panel displays, which are self emitting, adapted to employ low power, and lighter in weight and smaller in volume than cathode ray tubes are being employed instead of cathode ray tubes. There are various flat panel displays, e.g., liquid crystal displays (LCDs), field emission displays (FEDs), plasma display panels (PDPs), and organic light emitting diode (OLED) displays.

Organic light emitting displays display an image using OLEDs, which generate and emit light as a result of recombination of electrons and holes.

In general, OLED displays have various advantages, e.g., excellent color reproduction, thin thickness, etc. OLED displays are being employed in a variety of devices, e.g., mobile phones, personal digital assistants (PDAs), MP3s, etc.

It is desired for flat panel displays, e.g., OLED displays, to display images at higher resolution. Therefore, a pixel structure capable of displaying images at higher resolution is desired.

Moreover, with regard to OLED displays, an emitting layer is formed between an anode electrode and a cathode electrode, and red, green, and blue colors may be displayed based on a kind of the emitting layer. Currently, in general, blue emitting layers are more easily deteriorated and have a relatively shorter lifetime in comparison to other emitting layers.

### SUMMARY

Embodiments are therefore directed to a pixel employable in an organic light emitting display and an organic light emitting display employing such a pixel, which substantially overcome one or more of the problems due to the limitations and disadvantages of the related art.

It is therefore a feature of an embodiment to provide a pixel structure adapted for higher definition and to have a relatively longer lifespan than comparable conventional pixels.

It is therefore a separate feature of an embodiment to provide an organic light emitting display including a pixel structure adapted for higher definition and to have a relatively longer lifespan than comparable conventional organic light emitting displays.

It is therefore a separate feature of an embodiment to provide a structure of a pixel having a reduced size, which may more easily enable higher resolution, relative to comparable conventional pixels.

It is therefore a separate feature of an embodiment to provide a structure of a pixel adapted to reduce an occurrence of black spots relative to comparable conventional pixels.

It is therefore a separate feature of an embodiment to provide a pixel and/or an organic light emitting display that is adapted to at least reduce an occurrence of black spots resulting from a blue emitting layer, which generally has a higher occurrence of black spots than a red or a green emitting layer, relative to comparable conventional pixels and displays.

It is therefore a separate feature of an embodiment to provide a pixel and/or an organic light emitting display that is adapted to have a longer lifespan by at least reducing color deterioration of the pixels over driving time.

At least one of the above and other features and advantages may be realized by providing a pixel, including a red sub-pixel including a red emitting layer, a green sub-pixel including a green emitting layer, a first blue sub-pixel including a first blue emitting layer, a second blue sub-pixel including a second blue emitting layer, wherein the red emitting layer and the green emitting layer are symmetrically arranged and the first blue emitting layer and the second blue emitting layer are symmetrically arranged.

Each of the red emitting layer, the green emitting layer, the first blue emitting layer, and the second blue emitting layer may have a triangular shape.

Each of the triangular shaped areas of each of the red emitting layer, the green emitting layer, the first blue emitting layer, and the second blue emitting layer may include two sides having a same length.

The pixel may have a diamond or square shape, and one side of each of the red emitting layer, the green emitting layer, the first blue emitting layer, and the second blue emitting layer substantially corresponds to a respective side of the diamond or square shape of the pixel.

Each of the red emitting layer, the green emitting layer, the first blue emitting layer, and the second blue emitting layer may have a triangular shape, and a base of each of the triangular shaped emitting areas may extend along the respective side of the pixel.

Each of the red emitting layer, the green emitting layer, the first blue emitting layer, and the second blue emitting layer may have a same area.

The red emitting layer may be in contact with a red emitting layer of a first adjacent pixel, the green emitting layer may be in contact with a green emitting layer of a second adjacent pixel, the first blue emitting layer may be in contact with a first blue emitting layer of a third adjacent pixel, and the second blue emitting layer may be in contact with a second blue emitting layer of a fourth adjacent pixel.

The red emitting layer of the pixel and the red emitting layer of the first adjacent pixel may together define a square shape, the green emitting layer of the pixel and the green emitting layer of the second adjacent pixel may together define a square shape, the first blue emitting layer of the pixel and the first blue emitting layer of the third adjacent pixel may together define a square shape, and the second blue emitting layer of the pixel and the second blue emitting layer of the fourth adjacent pixel may together define a square shape.

The red emitting layer, the green emitting layer, the first blue emitting layer and the second blue emitting layer of the pixel may be spaced apart from each other by a predetermined margin, the margin having a cross-like shape therebetween.

The red emitting layer, the green emitting layer, the first blue emitting layer, and the second blue emitting layer may be arranged in a square space.

The red emitting layer and the green emitting layer may be symmetrically arranged about a first axis and the first blue emitting layer and the second blue emitting layer are symmetrically arranged about a second axis, the first axis being perpendicular to the second axis.

At least one of the above and other features and advantages may be separately realized by providing an organic light emitting display, including a pixel unit including a plurality of pixels adapted to emit light in response to a data signal and a scan signal supplied thereto, a data driver adapted to transmit the data signals to the pixel unit, a scan driver adapted to transmit the scan signals to the pixel unit, wherein each of the pixel includes a red sub-pixel including a red emitting layer, a green sub-pixel including a green emitting layer, a first blue sub-pixel including a first blue emitting layer, and a second blue sub-pixel including a second blue emitting layer, wherein the red emitting layer and the green emitting layer are symmetrically arranged and the first blue emitting layer and the second blue emitting layer are symmetrically arranged.

For each of the pixels, each of the red emitting layer, the green emitting layer, the first blue emitting layer, and the second blue emitting layer may have a triangular shape.

Each of the red emitting layer, the green emitting layer, the first blue emitting layer, and the second blue emitting layer may have a same area.

For each of the pixels surrounded by others of the plurality of pixels, the red emitting layer may be in contact with a red emitting layer of a first respective adjacent pixel, the green emitting layer may be in contact with a green emitting layer of a second respective adjacent pixel, the first blue emitting layer may be in contact with a first blue emitting layer of a third respective adjacent pixel, and the second blue emitting layer may be in contact with a second blue emitting layer of a fourth respective adjacent pixel.

For each pixel pair of the plurality of pixels arranged adjacent to each other, the pixels of the pixel pair may be symmetric about an axis extending therebetween.

The red emitting layer, the green emitting layer, the first blue emitting layer, and the second blue emitting layer may be arranged in a square space.

At least one of the above and other features and advantages may be separately realized by providing a pixel including a plurality of emitting layers adapted to emit light of a plurality of colors, the plurality of emitting layers may be symmetrically arranged about a center of the pixel, the plurality of emitting layers including a red emitting layer, a green emitting layer, a first blue emitting layer, and a second blue emitting layer.

The red emitting layer and the green emitting layer may be symmetrically arranged about a first axis passing through the center of the pixel and the first blue emitting layer and the second blue emitting layer may be symmetrically arranged about a second axis passing through the center of the pixel, the first axis may be perpendicular to the second axis.

Each of the red emitting layer, the green emitting layer, the first blue emitting layer, and the second blue emitting layer may have a triangular shape, and a base of each of the triangular shaped emitting areas extends along a respective side of the pixel.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic diagram of an exemplary embodiment of a structure of an organic light emitting display;

FIG. 2A illustrates a schematic diagram of an exemplary embodiment of an organic light emitting diode (OLED) employable in the organic light emitting display of FIG. 1;

FIG. 2B illustrates a schematic diagram of the exemplary OLED of FIG. 2A including electrons and holes that may result from a cathode layer and an anode layer, respectively, thereof;

FIG. 3 illustrates a plan view of a first exemplary embodiment of a pixel shape that may result from a first exemplary arrangement of emitting layers of an OLED employable in the organic light emitting display of FIG. 1;

FIG. 4 illustrates a plan view of a second exemplary embodiment of a pixel shape that may result from a second exemplary arrangement of emitting layers of an OLED employable in the organic light emitting display of FIG. 1; and

FIG. 5 illustrates a plan view of a pixel shape of an emitting layer of an OLED for setting forth a comparative example.

### DETAILED DESCRIPTION

Korean Patent Application No. 10-2009-0071278, filed on Aug. 3, 2009, in the Korean Intellectual Property Office, and entitled: “Pixel Structure and Organic Light Emitting Display Using the Same” is incorporated by reference herein in its entirety.

Exemplary embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the following detailed description, only certain exemplary embodiments of the present invention have been shown and described, simply by way of illustration. In the drawing figures, the dimensions of layers and regions may be exaggerated for clarity of illustration. Accordingly, the drawings and description are to be regarded as illustrative in nature and not restrictive. In addition, unless specified otherwise, when an element is referred to as being “on” or “under” another element, it can be directly on or under the another element or be indirectly on or under the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements throughout the specification.

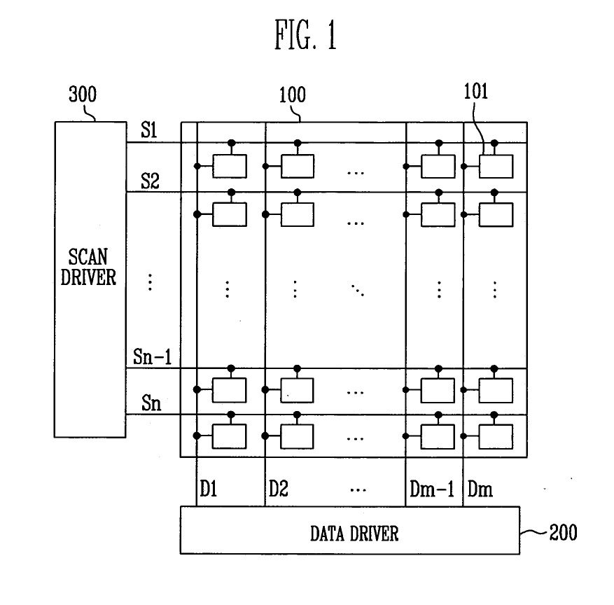

FIG. 1 illustrates a schematic diagram of an exemplary embodiment of a structure of an organic light emitting display. Referring to FIG. 1, an organic light emitting display (OLED) may include a pixel unit 100, a data driver 200, and a scan driver 300.

A plurality of pixels 101 may be arranged in the pixel unit 100. Each of the pixels 101 may include an organic light emitting diode (OLED) (not shown) for emitting light in response to the flow of electric current. The pixels 101 may be arranged in a matrix pattern including rows extending along a first direction and columns extending along a second direction that crosses, e.g. perpendicularly, the first direction. The pixel unit 100 may include n scan lines S1, S2, . . . , Sn-1, and Sn and m data lines D1, D2, . . . , Dm-1, and Dm. The scan lines S1 to Sn may extend along the row direction. The scan lines S1 to Sn may transmit scan signals. The data lines D1 to Dm may extend along the column direction. The data lines D1 to Dm may transmit data signals.

The pixel unit 100 may be driven by a first power supply (not shown) and a second power supply (not shown). The pixel unit 100 may emit light to display an image when current flows through the OLED by the scan signals, the data signals, the first power supply, and the second power supply.

The data driver 200 may generate data signals using an image signal, e.g., R-G-B-data including red, blue, and green color components. The data driver 200 may be electrically connected to the data lines D1 to Dm of the pixel unit 100, and may supply the generated data signals to the pixel unit 100.

The scan driver 300 may generate the scan signals. The scan driver 300 may be electrically connected to the scan lines S1 to Sn, and may transmit the respective scan signals to a respective row of the pixel unit 100.

The generated data signals output from the data driver 200 and the generated scan signals output from the scan driver 300 may be transmitted to the pixels 101, respectively. For example, while a respective scan signal is supplied to the second scan line S2, the pixels 101 associated with the second scan line S2 may receive respective ones of the data signals supplied to the data lines D1 to Dm, and a v voltage corresponding to the respective data signals may be respectively supplied to the pixels 101 of the second row.

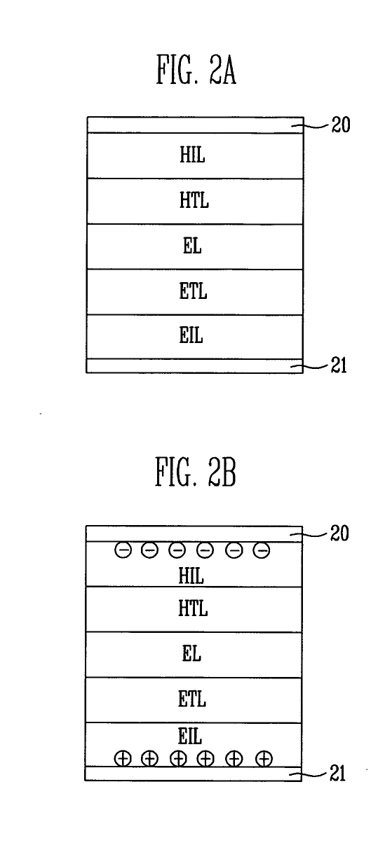

FIG. 2A illustrates a schematic diagram of an exemplary embodiment of an organic light emitting diode (OLED) employable in the organic light emitting display of FIG. 1, and FIG. 2B illustrates a schematic diagram of the exemplary OLED of FIG. 2A including electrons and holes that may result from a cathode layer and an anode layer, respectively, thereof.

Referring to FIGS. 2A and 2B, the OLED may include an emitting layer EL, a hole transfer layer HTL, an electron transfer layer ETL, an anode electrode 20, and a cathode electrode 21. The hole transfer layer HTL and the electron transfer layer ETL may be arranged between the anode electrode 20 and the cathode electrode 21.

The anode electrode 20 may be electrically connected to the first power supply, and may supply holes to the emitting layer EL. The cathode electrode 21 may be electrically connected to the second power supply, and may supply electrons to the emitting layer EL. The second power supply may have a lower voltage than the first power supply. That is, referring to FIG. 2B, the anode electrode 20 may have a relatively higher positive (+) potential than that of the cathode electrode 21, and the cathode electrode 21 may have a relatively lower negative (−) potential than that of the anode electrode 20.

The hole transfer layer HTL may accelerate holes fed from the anode electrode 20, and may supply the accelerated holes to the emitting layer EL. The electron transfer layer ETL may accelerate electrons fed from the cathode electrode 21, and may supply the accelerated electrons to the emitting layer EL. The holes fed from the hole transfer layer HTL may collide with the electrons fed from the electron transfer layer ETL in the emitting layer. As a result of the electrons and the holes that may recombine in the emitting layer EL, light may be generated. The emitting layer EL may include organic material, and may generate any one of red (R) light, green (G) light, and blue (B) light when the electrons recombine with the holes.

Referring still to FIGS. 2A and 2B, the OLED may further include a hole injection layer HIL and an electron injection layer EIL. The hole injection layer HIL may be arranged between the hole transfer layer HTL and the anode electrode 20. The electron injection layer EIL may be arranged between the electron transfer layer ETL and the cathode electrode 21. The hole injection layer HIL may supply holes to the hole transfer layer HTL. The electron injection layer EIL may supply electrons to the electron transfer layer ETL.

As discussed above, the emitting layer EL may emit any one light of red light, green light, and blue light as a result of recombination of the electrons and the holes. In general, an emitting layer for emitting red light and an emitting layer for emitting green light may each have a longer lifespan than that of an emitting layer for emitting blue light. Therefore, over time, when a same amount of current flows through a red emitting layer for red light, a green emitting layer for green light, and a blue emitting layer for blue light, light emitted from the blue emitting layer may be remarkably reduced in comparison to light emitting from the red and green emitting layers. To compensate for such a reduction in light emission, an area of the blue emitting layer may be increased, e.g., widened, relative to an area of the green and red emitting layers. For example, the red and green emitting layers may each have a same area and the blue emitting layer may have an area that is twice that of the red or green emitting layer. By increasing, e.g., widening, an area of the blue emitting layer, even when a current of a magnitude less than a current supplied to each of a red emitting layer and a green emitting layer is supplied to a blue emitting layer, the blue emitting layer may have a same and/or substantially same brightness as that of each of the red and green emitting layers.

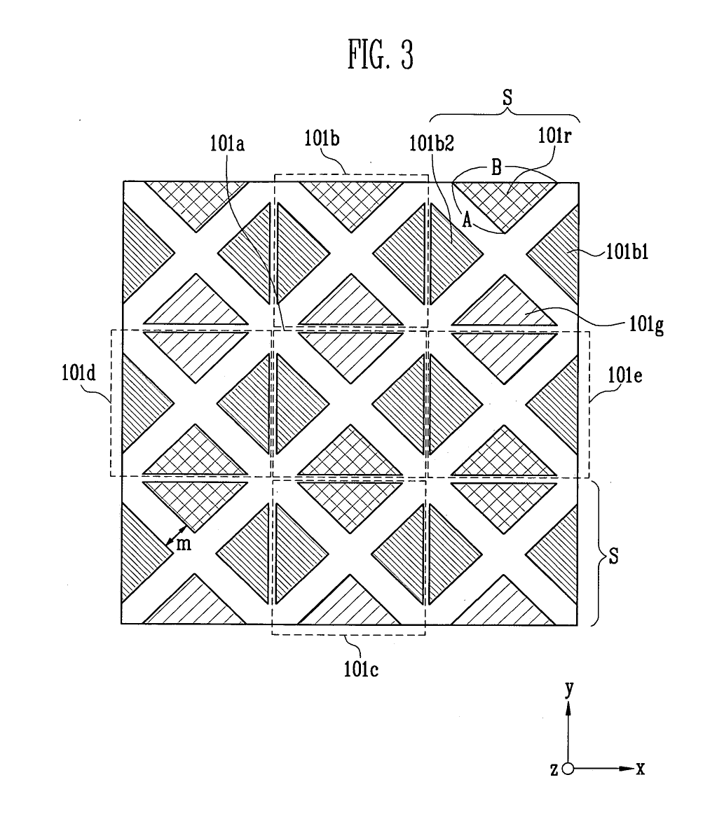

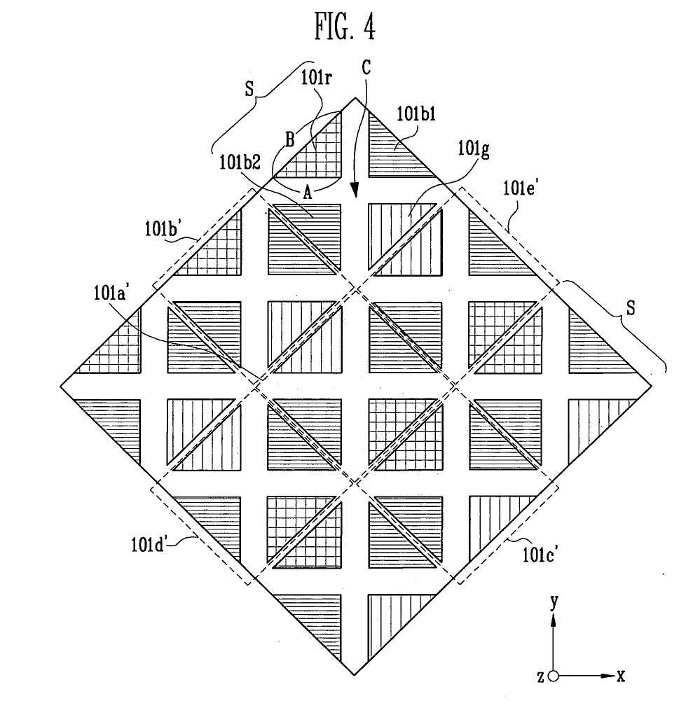

FIG. 3 illustrates a plan view of a first exemplary embodiment of a pixel shape that may result from a first exemplary arrangement of emitting layers of an OLED employable in the organic light emitting display of FIG. 1. FIG. 4 illustrates a plan view of a second exemplary embodiment of a pixel shape that may result from a second exemplary arrangement of emitting layers of an OLED employable in the organic light emitting display of FIG. 1. In general, the exemplary arrangement of FIG. 4 substantially corresponds to the exemplary arrangement of FIG. 3, except that, in the exemplary arrangement of FIG. 3, the pixels 101 are arranged such that each of the pixels 101 has a square configuration relative to an x-y axes, and in the exemplary arrangement of FIG. 4, the pixels 101′ are arranged such that each of the pixels 101′ has a diamond configuration relative to the x-y axes.

Referring to FIGS. 3 and 4, the plurality of pixels 101, 101′ may be classified into a first pixel 101a, 101a′, a second pixel 101b, 101b′, a third pixel 101c, 101c′, a fourth pixel 101d, 101d′, and a fifth pixel 101e, 101e′. Each of the plurality of pixels 101, 101′ may include a red sub-pixel, a green sub-pixel, a first blue sub-pixel, and a second blue sub-pixel. A driving circuit (not shown) for supplying current to the plurality of pixels 101 may be provided, e.g., below the pixels 101. Emitting layers of each of the red sub-pixel, the green sub-pixel, the first blue sub-pixel, and the second blue sub-pixel may have a same area. However, because the blue pixels may be divided into the first and second blue sub-pixels, a total area of the emitting layer of the first and second blue sub-pixels may be wider than that of each of the emitting layers of the red sub-pixel and the green sub-pixel.

More particularly, referring to FIGS. 3 and 4, the red sub-pixel may include a red emitting layer 101r, the green sub-pixel may include a green emitting layer 101g, the first blue sub-pixel may include a first blue emitting layer 101b1, and the second blue sub-pixel may include a second blue emitting layer 101b2. The red emitting layer 101r, the green emitting layer 101g, and the blue emitting layers 101b1 and 101b2 may be formed on the driving circuit (not shown) using a mask.

As shown in FIGS. 3 and 4, the red emitting layer 101r, the green emitting layer 101g, and the blue emitting layers 101b1 and 101b2 may be separated by a distance due to a margin M, i.e. predetermined space. Such a margin M between adjacent ones of the red, green and blue emitting layers 101r, 101g, 101b1, 101b2 may increase an area of each of the pixels 101, 101′.

As a result, when the red sub-pixel, the green sub-pixel, and the blue sub-pixels are provided in a repeating pattern corresponding to adjacent pixels 101, 101′, there may be a first predetermined space between emitting layers of different colored sub-pixels and/or there may be a second predetermined space between emitting layers of sub-pixels associated with different, e.g., adjacent, pixels. Such predetermined spaces may increase an overall size, e.g., area, of each of the pixels 101, 101′. However, by arranging same color ones of the emitting layers adjacent/facing one another, the second predetermined space may be reduced and/or eliminated.

Referring to FIGS. 3 and 4, in embodiments, the emitting areas 101r, 101g, 101b1, 101b2 of each of the pixels may be arranged so as to reduce and/or minimize an area of each of the pixels 101, 101′. For example, in some embodiments, emitting layers 101r, 101g, 101b1, 101b2 of each of the pixels 101, 101′ may be arranged in a same pattern, but adjacent ones of the pixels 101, 101′ may be flipped such that same color ones of the emitting layers 101r, 101g, 101b of the adjacent ones of the pixels 101, 101′ may be arranged facing one another. For example, referring to FIGS. 3 and 4, the first pixel 101a, 101a′ may be arranged relative to the second pixel 101b, 101b′ such that green emitting layers 101g thereof face each other, the first pixel 101a, 101a′ may be arranged relative to the third pixel 101c, 101c′ such that red emitting layers 101r thereof face each other, and the first pixel 101a, 101a′ may be arranged relative to the fourth and fifth pixels 101d, 101d′, 101e, 101e′ such that blue emitting layers 101b thereof face other.

More particularly, referring to FIGS. 3 and 4, in some embodiments, the emitting layers 101r, 101g, 101b1, 101b2 of each of the pixels 101, 101′ may be arranged such that a space between adjacent ones of the pixels 101, 101′ is not required and/or is minimized by arranging the pixels 101, 101′ such that facing ones of emitting layers thereof correspond to a same color. In some embodiments, the pixels 101, 101′ may be arranged such that facing ones of the emitting layers corresponding to a same color may contact each other.

More particularly, referring to FIGS. 3 and 4, in some embodiments, each of the emitting layers 101r, 101g, 101b1, 101b2 may have, e.g., a triangular shape, and a base B of each of the triangular shaped emitting layers 101r, 101g, 101b1, 101b2 may extend along respective sides S of the pixels 101, 101′. The blue emitting layers 101b1, 101b2 may be arranged such that bases B thereof extend along a first set of opposing sides S of each of the pixels 101, 101′, and the green and red emitting layers 101g, 101r may be arranged such that bases B thereof extend along a second set of opposing sides S of each of the pixels 101, 101′. More particularly, referring to FIG. 3, the blue emitting layers 101b1, 101b2 of one of the pixels 101 may be symmetrically arranged about the y-axis, and the red and green emitting layers 101r, 101g of the same one of the pixels 101 may be symmetrically arranged about the x-axis. In some embodiments, the red, green and blue emitting layers 101r, 101g, 101b1, 101b2 may be symmetrically arranged about a center C of the respective pixel 101, 101′. In some embodiments, the triangular shaped emitting layers 101r, 101g, 101b1, 101b2 may define a cross-like shape within the respective pixel 101, 101′.

Referring to FIGS. 3 and 4, irrespective of the square or diamond like arrangement of the pixels 101, 101′, respective bases B of the same color emitting layers 101r, 101g, 101b may be aligned facing each other. As a result, facing ones of the triangular emitting layers, e.g., green emitting layers 101g of the first and second pixels 101a, 101b of the exemplary embodiment of FIG. 3, may form a substantially square or diamond like shape.

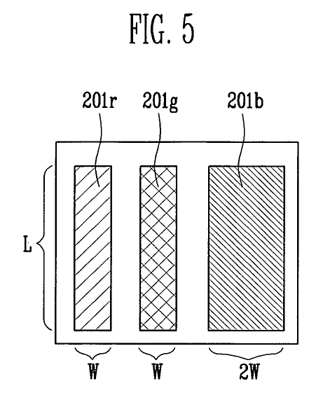

FIG. 5 illustrates a plan view of a pixel shape of an emitting layer of an OLED for setting forth a comparative example of pixel areas. In the OLED illustrated in FIG. 5, the OLED includes a red emitting layer 201r, a green emitting layer 201g, and a blue emitting layer 201b. The blue emitting layer 201b may have twice an area of each of the red emitting layer 201r and the green emitting layer 201g. For the following comparative example, it may be assumed that each of the red and green emitting layers 201r, 201g has a width W of 25 μm and a length L of 150 μm, the blue emitting layer 201b may have a width 2W of 50 μm wide and a length of 150 μm (3750 μm² for each of the emitting layers 201r, 201g and 7500 μm² for 201b), and a separating distance due to a margin between different colored emitting layers is 25 μm. With two complete margins between the three emitting layers 201b, 201g, 201r, and half of a margin (12.5 micrometers) on each side of the pixel of FIG. 5, a size of one such pixel is 175 μm by 175 μm.

Referring back to FIGS. 3 and 4, embodiments may provide smaller pixels including red, green and blue emitting layers of a same area as the comparative example of FIG. 5 by shaping and/or arranging the respective emitting layers differently. It should be understood that the specific dimensions discussed herein with regard to FIGS. 3 and 4 are merely exemplary in view of the dimensions described above with regard to the comparative example illustrated in FIG. 5. That is, embodiments are not limited to the specific dimensions described with reference to FIGS. 3 and 4.

More particularly, in the exemplary embodiments illustrated in FIGS. 3 and 4, each of the different colored emitting layers, e.g., the red, green and blue emitting layers 101r, 101g, 101b1+101b2, may have a same area but within a smaller sized pixel, i.e., pixel with smaller area than the pixel in the comparative example of FIG. 5. Equation 1 and Equation 2 below will be employed to provide an example of how each of the different colored emitting layers, i.e., the red, green or blue emitting layers 101r, 101g, 101b1+101b2 of FIGS. 3 and 4 may be sized and/or shaped to have a same area as that of the red, green and blue emitting layers 201r, 201g, 201b, respectively, of FIG. 5, while reducing a total size of the pixel. For example, each of the pixels 101, 101′ may be a square, and for each of the pixels 101, 101′ each of the red, green and blue emitting layers 101r, 101g, 101b1, 101b2 may be a triangle with two equal length sides A and a base B. Referring to Equation 1 below, for each of the emitting layers 101r, 101g, 101b1+101b2 to have the same area, i.e., (width W) (length L), of the emitting layers 201r, 201g, 202b, respectively, of FIG. 5, in such embodiments of FIGS. 3 and 4, each of the sides A may be may have a length of 86.6 μm.

WL=(25μm)(150μm)=½A²

A=86.6μm [Equation 1]

In such cases, a length of the base B of each of the red, green and blue emitting layers 101r, 101g, 101b1, 101b2 may be determined using the Pythagorean theorem such that (86.6 μm)²+(86.6 μm)²=B²=122.47 μm. In the exemplary embodiments of FIGS. 3 and 4, assuming each of the two sides A of each of the triangular shaped red, green and blue emitting layers 101r, 101g, 101b1, 101b2 have a length of 86.6 μm and the base B of each of the red, green and blue emitting layers 101r, 101g, 101b1, 101b2 have a length of 122.47 μm, each of the red, green and blue emitting layers 101r, 101g, 101b1+101b2 of FIGS. 3 and 4 may have a same area as the red, green and blue emitting layers 201r, 201g, 201b of FIG. 5, and, as may be determined from Equation 2 below, a total area of each of the pixels of FIGS. 3 and 4 may be smaller than the total area (175 μm by 175 μm) of the comparative pixel of FIG. 5.

$$S = \sqrt{2} ( A ) + 2 ( \frac{margin}{\sqrt{2}} ) \qquad [ Equation 2 ]$$

In Equation 2, S corresponds to a length of each side of each of the square or diamond shaped pixels 101, 101′ of FIGS. 3 and 4, and the margin M corresponds to the separating distance due to a margin M between different colored emitting layers, e.g., 25 μm. Under the conditions set forth above, S may be 158 μm. Thus, an area of each of the square or diamond shaped pixels of the exemplary embodiments of FIGS. 3 and 4 may be 158 μm by 158 μm, which is substantially smaller than the total area of 175 μm by 175 μm of the comparative pixel of FIG. 5, while including red, green and blue emitting layers 101r, 101g, 101b1+101b2 having a same area as the red, green and blue emitting layers 201r, 201g, 201b in FIG. 5. Thus, relative to the comparative example of FIG. 5, the size of each of the pixels of the exemplary embodiments of FIGS. 3 and 4 may be shortened in length and width by 17 μm.

Embodiments may provide a total size of pixels to be reduced while maintaining and/or increasing an area of each of the emitting layers, e.g., red, green and blue emitting layers. Thus, embodiments may provide a relatively smaller sized pixel that is adapted for achieving higher definition relative to comparable conventional pixels.

Embodiments may separately provide pixels in which a total area of a blue emitting layer, which generally have a higher occurrence of black spots than red or green emitting layers, is greater, e.g., double in area, than the each of the red and green emitting layers so that an occurrence of black spots may be reduced. In such embodiments, as an area, e.g., width, of the blue emitting layer, which may be more prone to deterioration, is increased, unintended color changes that may result while driving such a display device over time may be reduced.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A pixel, comprising:
a red sub-pixel including a red emitting layer;
a green sub-pixel including a green emitting layer;
a first blue sub-pixel including a first blue emitting layer; and
a second blue sub-pixel including a second blue emitting layer,
wherein the red emitting layer and the green emitting layer are symmetrically arranged and the first blue emitting layer and the second blue emitting layer are symmetrically arranged.

2. The pixel as claimed in claim 1, wherein each of the red emitting layer, the green emitting layer, the first blue emitting layer, and the second blue emitting layer has a triangular shape.

3. The pixel as claimed in claim 2, wherein each of the triangular shaped areas of each of the red emitting layer, the green emitting layer, the first blue emitting layer, and the second blue emitting layer includes two sides having a same length.

4. The pixel as claimed in claim 2, wherein the pixel has a diamond or square shape, and one side of each of the red emitting layer, the green emitting layer, the first blue emitting layer, and the second blue emitting layer substantially corresponds to a respective side of the diamond or square shape of the pixel.

5. The pixel as claimed in claim 4, wherein each of the red emitting layer, the green emitting layer, the first blue emitting layer, and the second blue emitting layer has a triangular shape, and a base of each of the triangular shaped emitting areas extends along the respective side of the pixel.

6. The pixel as claimed in claim 1, wherein each of the red emitting layer, the green emitting layer, the first blue emitting layer, and the second blue emitting layer has a same area.

7. The pixel as claimed in claim 1, wherein the red emitting layer is in contact with a red emitting layer of a first adjacent pixel, the green emitting layer is in contact with a green emitting layer of a second adjacent pixel, the first blue emitting layer is in contact with a first blue emitting layer of a third adjacent pixel, and the second blue emitting layer is in contact with a second blue emitting layer of a fourth adjacent pixel.

8. The pixel as claimed in claim 7, wherein the red emitting layer of the pixel and the red emitting layer of the first adjacent pixel together define a square shape, the green emitting layer of the pixel and the green emitting layer of the second adjacent pixel together define a square shape, the first blue emitting layer of the pixel and the first blue emitting layer of the third adjacent pixel together define a square shape, and the second blue emitting layer of the pixel and the second blue emitting layer of the fourth adjacent pixel together define a square shape.

9. The pixel as claimed in claim 1, wherein the red emitting layer, the green emitting layer, the first blue emitting layer and the second blue emitting layer of the pixel are spaced apart from each other by a predetermined margin, the margin having a cross-like shape therebetween.

10. The pixel as claimed in claim 1, wherein the red emitting layer, the green emitting layer, the first blue emitting layer, and the second blue emitting layer are arranged in a square space.

11. The pixel as claimed in claim 1, wherein the red emitting layer and the green emitting layer are symmetrically arranged about a first axis and the first blue emitting layer and the second blue emitting layer are symmetrically arranged about a second axis, the first axis being perpendicular to the second axis.

12. An organic light emitting display, comprising:
a pixel unit including a plurality of pixels adapted to emit light in response to a data signal and a scan signal supplied thereto;
a data driver adapted to transmit the data signals to the pixel unit;
a scan driver adapted to transmit the scan signals to the pixel unit,
wherein each of the pixel comprises:
a red sub-pixel including a red emitting layer;
a green sub-pixel including a green emitting layer;
a first blue sub-pixel including a first blue emitting layer; and
a second blue sub-pixel including a second blue emitting layer,
wherein the red emitting layer and the green emitting layer are symmetrically arranged and the first blue emitting layer and the second blue emitting layer are symmetrically arranged.

13. The organic light emitting display as claimed in claim 12, wherein for each of the pixels, each of the red emitting layer, the green emitting layer, the first blue emitting layer, and the second blue emitting layer has a triangular shape.

14. The organic light emitting display as claimed in claim 12, wherein each of the red emitting layer, the green emitting layer, the first blue emitting layer, and the second blue emitting layer has the same area.

15. The organic light emitting display as claimed in claim 12, wherein for each of the pixels surrounded by others of the plurality of pixels, the red emitting layer is in contact with a red emitting layer of a first respective adjacent pixel, the green emitting layer is in contact with a green emitting layer of a second respective adjacent pixel, the first blue emitting layer is in contact with a first blue emitting layer of a third respective adjacent pixel, and the second blue emitting layer is in contact with a second blue emitting layer of a fourth respective adjacent pixel.

16. The organic light emitting display as claimed in claim 12, wherein for each pixel pair of the plurality of pixels arranged adjacent to each other, the pixels of the pixel pair are symmetric about an axis extending therebetween.

17. The organic light emitting display as claimed in claim 12, wherein the red emitting layer, the green emitting layer, the first blue emitting layer, and the second blue emitting layer are arranged in a square space.

18. A pixel, comprising:
a plurality of emitting layers adapted to emit light of a plurality of colors, the plurality of emitting layers being symmetrically arranged about a center of the pixel, the plurality of emitting layers including a red emitting layer, a green emitting layer, a first blue emitting layer, and a second blue emitting layer.

19. The pixel as claimed in claim 18, wherein the red emitting layer and the green emitting layer are symmetrically arranged about a first axis passing through the center of the pixel and the first blue emitting layer and the second blue emitting layer are symmetrically arranged about a second axis passing through the center of the pixel, the first axis being perpendicular to the second axis.

20. The pixel as claimed in claim 18, wherein each of the red emitting layer, the green emitting layer, the first blue emitting layer, and the second blue emitting layer has a triangular shape, and a base of each of the triangular shaped emitting areas extends along a respective side of the pixel.
